(19) United States
(12) Patent Application Publication
(10) Pub. No.: US 2019/0252414 A1
(43) Pub. Date: Aug. 15, 2019

(54) METHOD FOR MANUFACTURING THIN FILM TRANSISTOR

(71) Applicant: SHENZHEN ROYOLE TECHNOLOGIES CO. LTD., Shenzhen, Guangdong (CN)

(72) Inventors: Jigang ZHAO, Shenzhen, Guangdong (CN); Ze YUAN, Shenzhen, Guangdong (CN); Xiaojun YU, Shenzhen, Guangdong (CN); Peng WEI, Shenzhen, Guangdong (CN); Amit GUPTA, Shenzhen, Guangdong (CN); Ping LU, Shenzhen, Guangdong (CN); Tina TSONG, Shenzhen, Guangdong (CN); Haojun LUO, Shenzhen, Guangdong (CN); Eric Kai-Hsiang YU, Shenzhen, Guangdong (CN)

(21) Appl. No.: 16/329,291

(22) PCT Filed: Aug. 29, 2016
(86) PCT No.: PCT/CN2016/097132

§ 371 Date: Feb. 28, 2019

(51) Int. Cl. H01L 27/12; H01L 29/786; H01L 21/8234

(52) U.S. Cl. CPC H01L 27/127; H01L 27/1218; H01L 2021/775; H01L 21/8234; H01L 29/786

(57) ABSTRACT

The method for manufacturing a thin film transistor includes sequentially forming a gate electrode on a surface of a substrate, forming a gate insulating layer covering the surface of the substrate and the gate electrode, forming an active layer and an etching stop layer above the gate electrode, forming a metal layer including a first region covering the etching stop layer and a pair of second regions connecting both sides of the first region on the active layer, and forming a photosensitive layer on the metal layer; removing a portion of the photosensitive layer to expose a portion of the first region; removing the exposed portion of the first region with the remaining first region having a height same as the remaining photosensitive layer located at two opposite sides of the etching stop layer; and removing the remaining photosensitive layer.

### RELATED APPLICATION

The present application is a National Phase of International Application Number PCT/CN2016/097132, filed Aug. 29, 2016.

### TECHNICAL FIELD

The present disclosure relates to the technical field of manufacturing thin film transistors, and more particularly relates to a method for manufacturing a thin film transistor.

### BACKGROUND

Thin-film transistors (TFT) array substrates are widely used in different types of displays, such as LCD or AMOLED displays. With the increase of the size of displays, large currents for TFTs are required to support higher resolutions. For the thin film transistor of bottom gate type, an etching stop layer is disposed on an active layer for protecting the active layer in the manufacturing process to ensure the stability of the electrical properties of the active layer. Affected by the general setting of the TFT, the etching stop layer may increase the length of the channel between the source electrode and drain electrode to the active layer, thereby affecting the resolution of the display.

### SUMMARY

Embodiments of the present disclosure provide a method for manufacturing a thin film transistor, which solves the technical problem that the etching stop layer connected to the source electrode and the drain electrode increases the length of the channel so that a large parasitic capacitance is generated to affect the resolution of a display screen.

A method for manufacturing a thin film transistor includes forming a gate electrode, a gate insulating layer and an active layer on a substrate; forming a protective layer on the gate insulating layer and the active layer; patterning the protective layer to form an etching stop layer on the active layer; forming a metal layer on the active layer, the etching stop layer, and the gate insulating layer; coating a photosensitive layer on a first region of the metal layer; removing a portion of the photo-sensitive layer to expose a portion of the metal layer covering the etching stop layer; and removing the metal layer to expose a portion of the etching stop layer.

The method for manufacturing a thin film transistor of the present disclosure uses the photosensitive layer to cover the metal layer and then removes the portion of the etching stop layer by a plasma ashing process to define the metal layer to be removed to form a source electrode and a drain electrode such the self-alignment of the drain electrode and the source electrode is achieved through the etching stop layer, thereby accurately defining the locations of the drain electrode and the source electrode. Furthermore, the present disclosure directly defines the source electrode and the drain electrode on the active layer such that, the length of the channel region of the source electrode and the drain electrode to the active layer is reduced, thereby reducing the generation of parasitic capacitance.

### BRIEF DESCRIPTION OF THE DRAWINGS

To illustrate the technical solutions in the embodiments of the present disclosure more clearly, the companying drawings to be used in the embodiments will be briefly described below. Obviously, the drawings in the following description are only some embodiments of the present disclosure. Those skilled in the art can also obtain other companying drawings based on these companying drawings without paying any creative effort.

FIG. 1 is a flowchart of a method for manufacturing a thin film transistor according to a first embodiment of the present disclosure.

FIG. 2 to FIG. 13 are schematic cross-sectional views of each processes of the method for manufacturing the thin film transistor illustrated in FIG. 1, respectively.

FIG. 14 is a flow chart of a method for manufacturing a thin film transistor according to a second embodiment of the present disclosure.

FIG. 15 to FIG. 20 are schematic cross-sectional views of processes of the method for manufacturing the thin film transistor illustrated in FIG. 14, respectively.

### DETAILED DESCRIPTION OF ILLUSTRATED EMBODIMENTS

Technical solutions of the embodiments of present disclosure will be clearly and completely described in detail below with reference to the accompanying drawings.

The present disclosure provides a thin film transistor used in a liquid crystal display screen or an organic display screen.

As illustrated in FIG. 1, a method for manufacturing a thin film transistor according to a first embodiment of the present disclosure includes operations at the following blocks.

At block S1, forming a gate electrode, a gate insulating layer, and an active layer on a substrate.

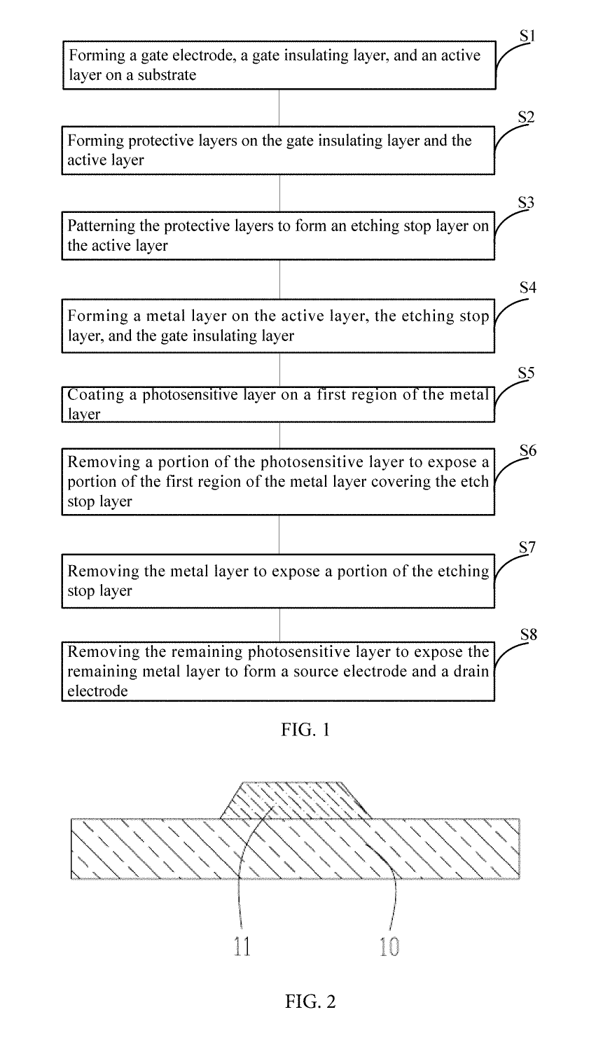

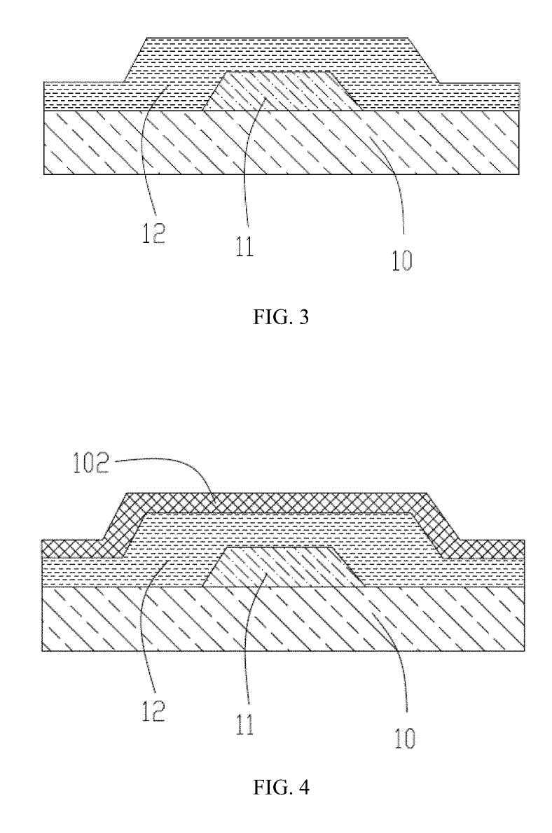

Also referring to FIG. 2, operations at block S1 further includes operations at the following blocks S11, 512, and 513. At block S11, a substrate 10 is provided and a gate electrode 11 is formed at a surface of the substrate 10. At block S12, a gate insulating layer 12 is formed at the substrate 10 and the gate electrode 11, as illustrated in FIG. 3. The substrate 10 is made of a flexible material. Specifically, the substrate 10 is made of polyimide or polyethylene naphthalate. In other embodiments, the substrate 10 includes a flexible base layer and a support layer supporting the flexible base layer. The support layer is made of glass, metal, or plastic. The gate electrode 11 is formed by coating a metal material on the surface of the substrate 10 and removing the excessive metal material by a patterning process. The patterning process described herein includes existing patterning processes, such as photomasking, development, etching, and the like.

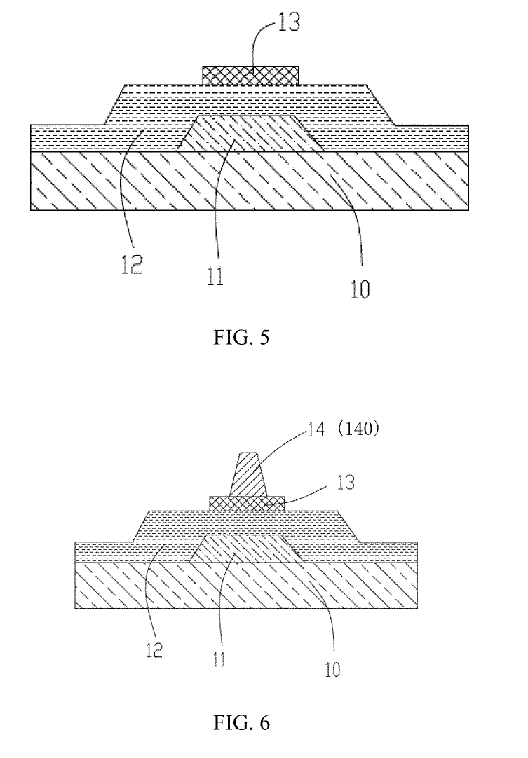

Referring to FIG. 4 and FIG. 5, at block S13, an active layer 13 is formed on the gate insulating layer 12 and located above the gate electrode 11. Specifically, a semiconductor layer 102 is formed on a surface of the gate insulating layer 12 facing away from the substrate 10. The semiconductor layer 102 is patterned to form the active layer 13. The active layer 13 is directly located above the gate electrode 11, with a projection of the active layer 13 falling within the gate electrode 11. The material of the semiconductor layer 102 is indium gallium zinc oxide (IGZO), zinc oxide (ZnO), indium zinc oxide (InZnO), zinc tin oxide (ZnSnO), low temperature polycrystalline silicon, or amorphous silicon. The gate insulating layer 12 is made of silicon oxide (SiOx), silicon nitride (SiNx), or silicon oxynitride (SiNxOy).

Referring to FIG. 6, at block S2, a protective layer 140 is formed on the gate insulating layer 12 and the active layer 13. The protective layer 140 may be an organic material, an inorganic material, or a mixture thereof an organic material and an inorganic material.

At block S3, the protective layer 140 is patterned to form an etching stop layer 14 on the active layer 13. Specifically, operations at this block includes forming an organic layer (not illustrated) on the active layer 13 and the gate insulating layer 12, and then patterning the organic layer to form the etching stop layer 14 located in the middle of the active layer 13. The etching stop layer 14 is operated to protect the active layer 13. The material of the etching stop layer 14 is an organic material, such as a photoresist or other photosensitive organic material, which may easily be removed by solvents or other chemicals without damaging the active layer 13. It may be understood that the etching stop layer 14 may be retained in other embodiments.

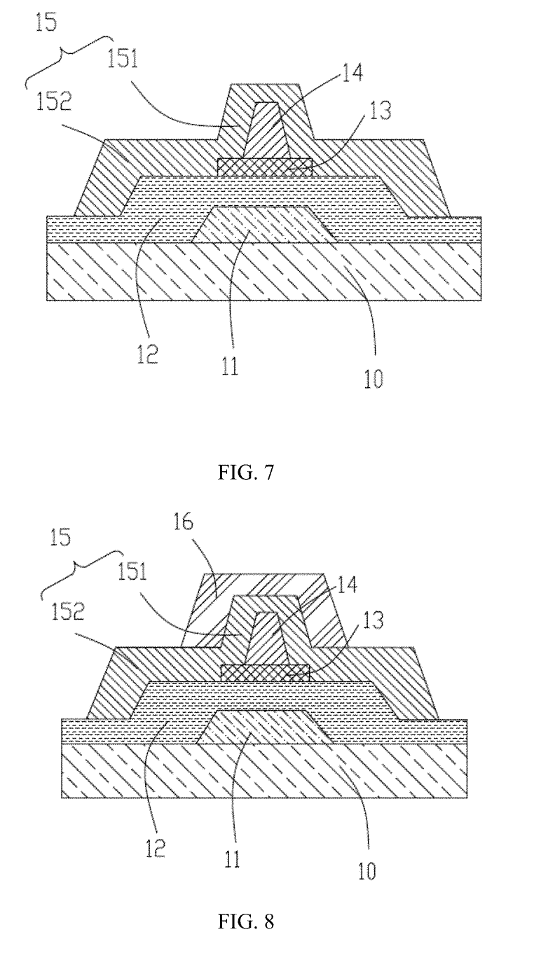

Referring to FIG. 7 and FIG. 8, at block S4, a metal layer 15 is formed on the active layer 13, the etching stop layer 14, and the gate insulating layer 12. The metal layer 15 includes a first region 151 with its orthographic projection covering the etching stop layer 14 and the active layer 13, and a pair of second regions 152 respectively connected to two opposite sides of the first region 151.

Specifically, when forming the first region 151 and the second region 152, the first region 151 covers an external surface of the etching stop layer 14 and the entire external surface of the active layer 13, and the second regions 152 are connected to the first region 151 and located at two sides of the active layer 13.

At block S5, a photosensitive layer 16 is coated on the first region 151 of the metal layer 15. Referring to FIG. 8, operations at this block includes covering the first region 151 of the metal layer 15 with a photoresist or a photosensitive organic material; forming the photosensitive layer 16 with its orthographic projection covering the active layer 13 and the etching stop layer 14 through the patterning the photoresist or the photosensitive organic material. The photosensitive layer 16 covers the first region 151 of the metal layer 15.

At block S6, a portion of the photosensitive layer 16 is removed to expose a portion of the first region 151 of the metal layer 15 covering the etching stop layer 14, as illustrated in FIG. 10. Operations at block S6 further includes operations at the following blocks S61 and S62.

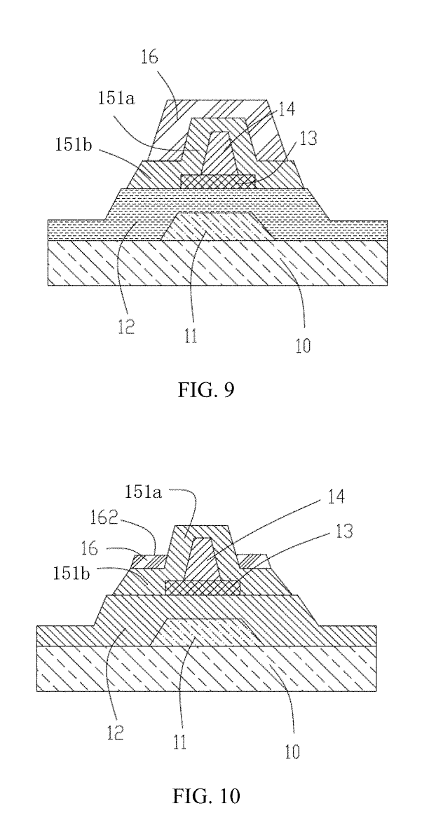

Referring to FIG. 9, operations at block S61, a portion of the metal layer 15 other than the first region 151 of the metal layer 15 located at both sides of the photosensitive layer 16, that is, the second regions 152 of the metal layer 15, is removed. In this block, the portion of the metal layer 15 other than the first region 151 may be removed by a wet etching process or a dry etching process. The first region 151 is covered by the photosensitive layer 16. The first region 151 further includes a first part 151a having an inverted U-shape and a second part 151b connected two opposite sides of the first part 151a.

Referring to FIG. 10, at block S62, a portion of the photosensitive layer 16 is removed to expose the first part 151a of the first region 151. At this block, the portion of the photosensitive layer 16 is removed by a plasma ashing process to expose the first part 151a of the first region 151 covering the etching stop layer 14, such that the remaining photosensitive layer 16 covers the second part 151b of the first region 151 of the metal layer 15 and a top wall of the remaining the photosensitive layer 16 forms a self-aligned plane 162 located at both sides of the exposed first part 151a of the metal layer 15. Specifically, the first part 151a of the first region 151 is with its orthographic projection located at the active layer 13 and the second part 151b is with its orthographic projection located at both sides of the active layer 13. The portion of the photosensitive layer 16 is removed to expose the first part 151a of the first region 151 with its orthographical projection located at the active layer 13 and with a height higher than the remaining photosensitive layer 16. The remaining photosensitive layer 16 is located on the second part 151b and forms the self-aligned plane 162 at a top surface of the remaining photosensitive layer 16. At this block, the patterning process of the mask mode is omitted. The portion of the photosensitive layer 16 is removed by the plasma ashing process, thereby avoiding the introduction of foreign reagents and the like to the active layer 13 or the metal layer 15 in the manufacturing process.

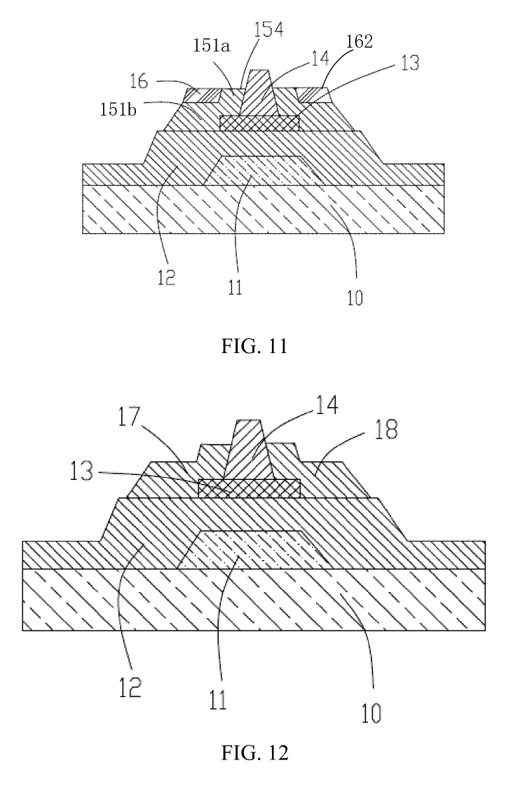

Referring to FIG. 11, at block S7, the metal layer 15 is removed to expose a portion of the etching stop layer 14. By an etching process, a portion of the first part 151a of the first region 151 of the metal layer 15 is removed and the etching stop layer 14 is exposed. A surface 154 of the remaining first part 151a of the metal layer 15 is aligned with the self-aligned plane 162.

Referring to FIG. 12, at block S8, the remaining photosensitive layer 16 is removed to expose the remaining metal layer 15 to form a source electrode 17 and a drain electrode 18.

The remaining first part 151a of the first region 151 of the metal layer 15 at one side of the etching stop layer 14 and the second part 151b connected thereto form the source electrode 17. The remaining first part 151a of the first region 151 of the metal layer 15 on the other side of the etching stop layer 14 and the second part 151b connected thereto form the drain electrode 18. At this block, the exposed first region 151 is removed by a patterning process to leave the remaining first region 151 located at both sides of the etching stop layer 14 and connected to the second part 151b. The remaining first region 151 and the second part 151b form the drain electrode 18 and the source electrode 17. Operations at this block includes following operations.

Coating a photoresist layer on a surface of the exposed first part 151a of the first region 151 and a surface of the remaining photosensitive layer 16;

Patterning the photoresist layer to remove a portion of the photoresist layer covering the remaining photosensitive layer 16;

Etching the remaining photosensitive layer 16 with the photoresist layer as a mask to protect the exposed first region 151; and stripping the remaining photoresist layer to form the drain electrode 18 and the source electrode 17.

At block S9, the remaining photosensitive layer 16 is removed to expose the source electrode 17 and the drain electrode 18. The remaining photosensitive layer 16 refers to the photosensitive layer 16 covering the remaining first region 151. The source electrode 17 and the drain electrode 18 are separated from each other and connected to opposite sides of the active layer 13.

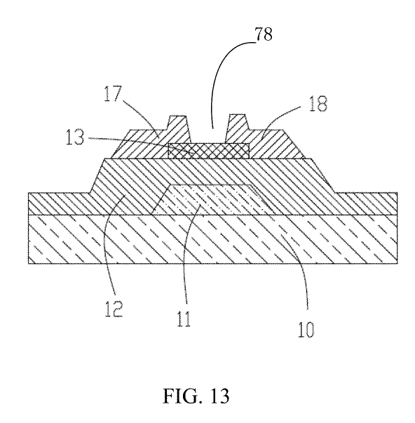

Referring to FIG. 13, at block S10 (not illustrated in FIG. 1), the etching stop layer 14 is removed to form a channel region 78 of the thin film transistor. Specifically, the etching stop layer 14 is removed by a patterning process to expose a gap between the source electrode 17 and the drain electrode 18. At this block, the source electrode 17, the drain electrode 18, and the portions of the source electrode 17 and the drain electrode 18 connecting with the etching stop layer 14 are simultaneously planarized.

In other embodiments, the method may not include operations at block S10. That is, the etching stop layer 14 is not removed and remained in the channel region 78 of the thin film transistor such that the etching stop layer 14 needs not to be treated by photolithograph finally. Therefore, the number of masks is saved, the process flow is reduced, and the strength of the entire thin film transistor is enhanced.

The method for manufacturing a thin film transistor of the present disclosure uses the etching stop layer 14 covering by the metal layer 15 and then removes a portion of the photosensitive layer 16 by a plasma ashing process to define the metal layer 15 to be removed to form the source electrode 17 and the drain electrode 18 to achieve the self-alignment of the source electrode 17 and the drain electrode 18 through the etching stop layer 14, thereby accurately defining the locations of the source electrode 17 and the drain electrode 18. Furthermore, comparing with forming the drain electrode and the source electrode connecting portions of the etching stop layer on the etching stop layer by masks in the related art, the present disclosure directly defines the source electrode 17 and the drain electrode 18 on the active layer 13. Therefore, the length of the channel region 78 between the source electrode 17 and the drain electrode 18 to the active layer 13 is reduced, thereby reducing the generation of parasitic capacitance. Additionally, a photomask patterning process is saved, the process flow is reduced, and costs are saved.

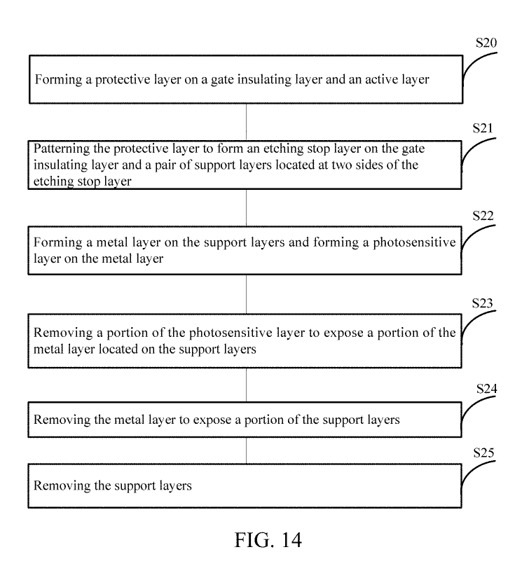

FIG. 14 illustrates a method for manufacturing a thin film transistor according to a second embodiment of the present disclosure. The second embodiment is different from the first embodiment is in that a support layer 45 and a support layer 46 are formed when an etching stop layer 44 is formed. In this embodiment, the two support layers 45, 46 finally form a source electrode and a drain electrode, connected to the active layers 43. The specific operations are as follows. The same operations as the above-described first embodiment will not be described again. The method for manufacturing a thin film transistor according to the second embodiment includes operations at the following blocks.

At block S20, a protective layer 40 is formed at a gate insulating layer 12 and an active layer 43. The protective layer 40 may be an organic material, an inorganic material or a mixture thereof The method of forming a gate electrode 11, the gate insulating layer 12 and the active layer 43 on a substrate 10 before the operations at block S20 is the same as the operations at block Si in the first embodiment, may refer to FIG. 1 to FIG. 3.

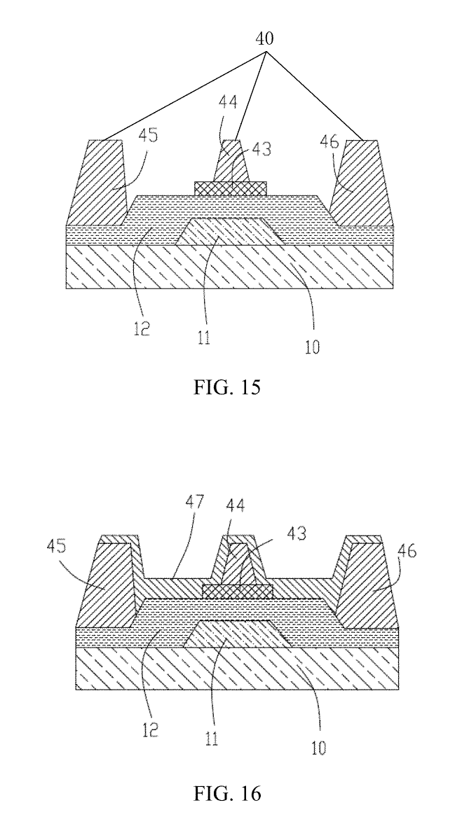

Referring to FIG. 15, at block S21, the protective layer 40 is patterned to form the etching stop layer 44 and the support layers 45, 46 located at both sides of the etching stop layer 44 on the gate insulating layer 12. The etching stop layer 44 and the support layers 45, 46 are formed by the same process, that is, in the present embodiment, the support layers 45, 46 at both sides of the etching stop layer 44 are formed when the etching stop layer 44 is formed, which saves the number of masks and reduces the process flow.

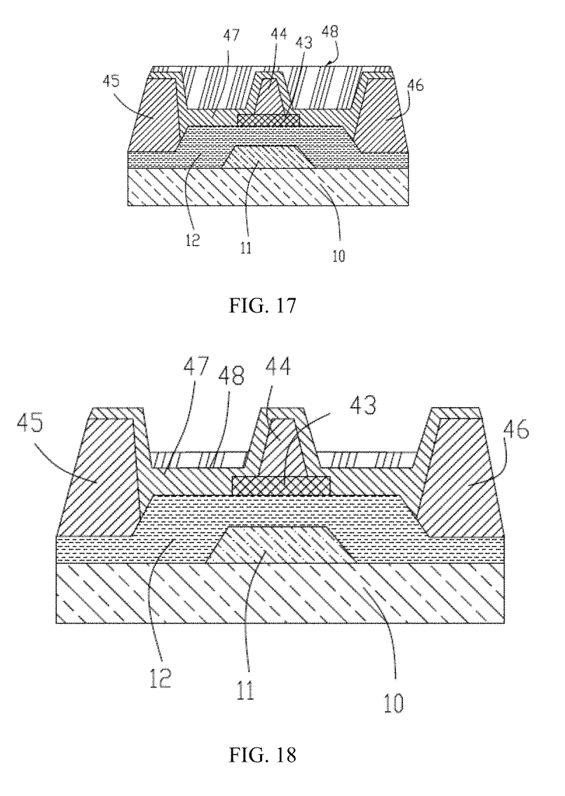

Referring to FIG. 16 and FIG. 17, at block S22, a metal layer 47 is formed on the etching stop layer 44 and the supporting layers 45, 46, and a photosensitive layer 48 is formed on the metal layer 47. The photosensitive layer 48 may be replaced by an organic layer with a planarization function. Operations at this block, operations at block S4 of the metal layer being formed on the active layer, the etching stop layer and the gate insulating layer, and operations at block S5 of the photosensitive layer being coated on the first region 151 of the metal layer 15, are performed by the same process. That is, at block S4, the metal layer may also cover the support layers, and the metal layer on the support layers is also covered by a photosensitive layer or an organic planarization layer, which may reduce a process.

Referring to FIG. 18, at block S23, removing a portion of the photosensitive layer 48 to expose a portion of the metal layer 47 located at the support layers 45, 46 and a portion of the metal layer 47 covering the etching stop layer 44 are performed by the same process. Operations at this block and block S6 in which a portion of the photosensitive layer 16 is removed to expose a portion of the first region 151 of the metal layer 15 covering the etching stop layer 14 are the same process. Another embodiment of operations at this block is that the support layers 45, 46 and the etching stop layer 44 are coated with an organic photosensitive planarization layer to be selectively removed by incomplete exposure and corresponding development.

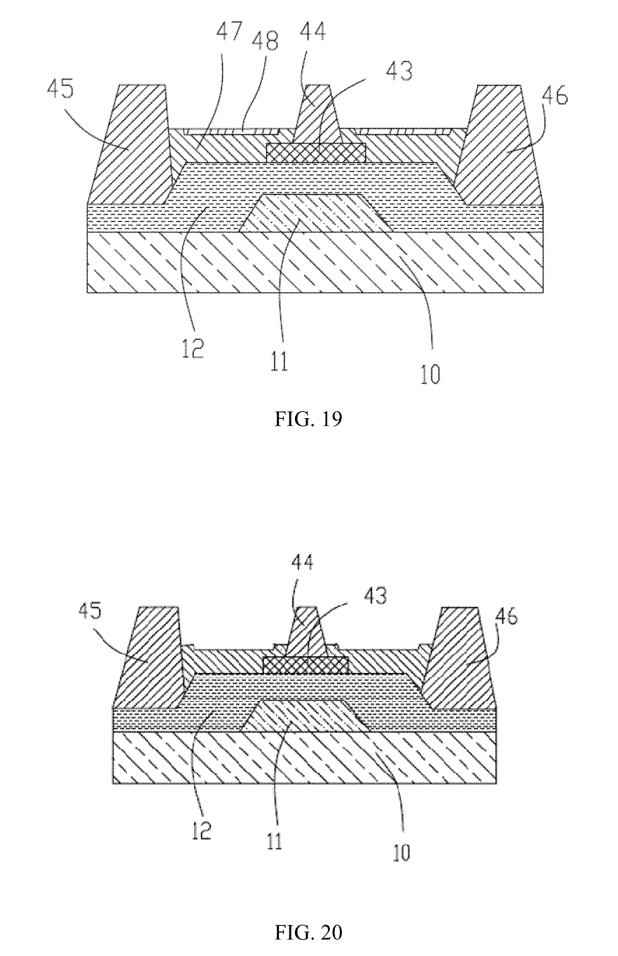

Referring to FIG. 19 and FIG. 20, at block S24, a portion of the metal layer 47 is removed to expose portions of the support layers 45, 46 and a portion of the etching stop layer 44 by the same process, which saves the number of masks and reduce the process flow.

In this embodiment, at block S25, the support layers 45, 46 are removed. Removing the support layers 45, 46 include removing the remaining photosensitive layer 48 first. In other embodiments, the support layers 45, 46 may be retained such that the support layers 45, 46 need not to be treated by photolithograph finally. Therefore, the number of masks is saved, the process flow is reduced, and the entire final strength of the thin film transistor is enhanced.

The above is only the preferred embodiments of the present disclosure. It is noted that those skilled in the art can also make several improvements and modifications without departing from the principles of the present disclosure. These improvements and modifications are intended to be included in the scope of the present disclosure.

What is claimed is:

1. A method for manufacturing a thin film transistor, comprising:
forming a gate electrode, a gate insulating layer, and an active layer on a substrate;
forming a protective layer on the gate insulating layer and the active layer;
patterning the protective layer to form an etching stop layer on the active layer;
forming a metal layer on the active layer, the etching stop layer, and the gate insulating layer;
coating a photosensitive layer on a first region of the metal layer;
removing a portion of the photosensitive layer to expose a portion of the first region of the metal layer covering the etching stop layer; and
removing a portion of the metal layer to expose a portion of the etching stop layer.

2. The method of claim 1, further comprising removing the remaining photosensitive layer to expose the remaining metal layer to form a source electrode and a drain electrode.

3. The method of claim 2, further comprising removing the etching stop layer to form a channel region of the thin film transistor.

4. The method of claim 2, wherein the removing a portion of the photosensitive layer to expose a portion of the first region of the metal layer covering the etching stop layer; and removing a portion of the metal layer to expose a portion of the etching stop layer, comprises:
removing the portion of the photosensitive layer by the plasma ashing process to expose the portion of the first region covering the etching stop layer and cause the remaining photosensitive layer to cover the remaining portion of the first region of the metal layer, and the remaining photosensitive layer located at two sides of the exposed first region of the metal layer forming a self-aligned plane; and
removing the exposed first region by an etch process to expose the etching stop layer, and a surface of the etched remaining first portion of the metal layer aligning with the self-aligned plane.

5. The method of claim 2, wherein the coating a photosensitive layer on a first region of the metal layer, comprises:
forming a photoresist layer on the first region of the metal layer, and patterning the photoresist layer to form the photosensitive layer with its orthographical projection covering the active layer and the etching stop layer.

6. The method of claim 5, wherein further comprising removing the metal layer other than the first region of the metal layer exposed at both sides of the photosensitive layer.

7. The method of claim 6, wherein the removing the metal layer other than the first region of the metal layer exposed at both sides of the photosensitive layer by a wet etching process or a dry etching process.

8. The method of claim 1, wherein the material of the protective layer is an organic material, an inorganic material, or a mixture thereof

9. The method of claim 1, further comprising:
patterning the protective layer to form two support layers at both sides of the etching stop layer on the gate insulating layer;
forming the metal layer on the support layers and forming the photosensitive layer on the metal layer;
removing the portion of the photosensitive layer to expose the portion of the metal layer located at the support layers and the portion of the metal layer covering the etching stop layer;
removing portions of the metal layer to expose portions of the support layers and a portion of the etching stop layer;
removing the support layers.

10. The method of claim 9, wherein the patterning the protective layer to form an etching stop layer on the gate insulating layer and two support layers at both sides of the etching stop layer are performed by the same process.

11. The method of claim 9, wherein the forming a metal layer on the support layers and forming a photosensitive layer on the metal layer and the forming the metal layer on the active layer, the etching stop layer, and the gate insulating layer, and the coating the photosensitive layer film on the first region of the metal layer are performed by the same process.

12. The method of claim 9, wherein the removing a portion of the photosensitive layer to expose a portion of the metal layer located at the support layers and the removing a portion of the photosensitive layer to expose a portion of the metal layer covering the etching stop layer are performed by the same process.

13. The method of claim 9, wherein the removing a portion of the metal layer to expose portions of the support layers and a portion of the etching stop layer are performed by the same process.

14. The method of claim 9, wherein the removing the support layers comprise removing the remaining photosensitive layer first.
